(19) United States
(12) Patent Application Publication
(10) Pub. No.: US 2007/0018251 A1
(43) Pub. Date: Jan. 25, 2007

(54) Semiconductor device and method for fabricating the same

(76) Inventors: Junji Hirase, Osaka (JP); Atsuhiro Kajiya, Hyogo (JP)

Correspondence Address: MCDERMOTT WILL & EMERY LLP, 600 13TH STREET, N.W., WASHINGTON, DC, 20005-3096, US

(21) Appl. No.: 11/489,539

(22) Filed: Jul. 20, 2006

(30) Foreign Application Priority Data
Jul. 20, 2005 (JP) 2005-209594

(51) Int. Cl. H01L 29/94

(52) U.S. Cl. 257/368

(57) ABSTRACT

In a MIEET, an impurity which changes a lattice constant is introduced into part of a gate electrode located on an isolation region. A stress which is generated in part of the gate electrode as a starting point and improves the mobility of carries is applied to a channel region with the part of the gate electrode.

### BACKGROUND OF THE INVENTION

1. Field of the Invention

The present invention relates to a structure of a semiconductor device and a method for fabricating the semiconductor device, and more particularly relates to a semiconductor device which achieves improvement of a driving force of a MISFET (metal insulator semiconductor field-effect transistor) and a method for fabricating the semiconductor device.

2. Description of the Prior Art

In recent years, as semiconductor integrated circuits with an increased degree of integration, a more effective function and an increased operation speed have been developed, a technique for intentionally applying a stress to a channel region of a MISFET to improve a mobility has been proposed.

FIG. 11A is a perspective view illustrating orientations and types of stresses which improve the mobility of carriers in an n-channel type MISFET. FIG. 11B is a schematic view illustrating orientations and types of stresses which improve the mobility of carriers in a p-channel type MISFET.

The n-channel type MISFET of FIG. 11A includes a substrate 201 having a p-type semiconductor region with a <110> channel orientation (which means that the channel orientation thereof is the <110> orientation), a gate insulation film 202 formed on the substrate 201, a gate electrode 203 formed on the gate insulation film 202 and n-type source/drain regions 204 formed in parts of in the substrate 201 located on both sides of the gate electrode 203, respectively. As shown in FIG. 11A, out of stresses applied to a channel region, each of a tensile stress 205 applied in the channel orientation, and a tensile stress 206 applied in the gate width direction and a compressive stress 207 applied in the substrate normal direction improves the mobility of the n-channel type MISFET.

On the other hand, the p-channel type MISFET with a <110> channel orientation shown in FIG. 11B includes a substrate 301 having an n-type semiconductor region, a gate insulation film 302 formed on the substrate 301, a gate electrode 303 formed on the gate insulation film 302 and p-type source/drain regions 304 formed in parts of the substrate 301 located on both sides of the gate electrode 303, respectively. As shown in FIG. 11B, out of stresses applied to a channel region, a compressive stress 305 applied in the channel orientation, a tensile stress 306 applied in the gate width direction and a tensile stress 307 applied to the substrate normal direction improve the mobility of carriers in the p-channel type MISFET. In this application, a “channel orientation” is the direction (i.e., a gate length direction) in which carriers travel in a channel region and a “gate width direction” is the direction which intersects with the channel orientation and in which a gate electrode extends in a MISFET.

As a method for applying these stresses, a method in which a channel layer of the n-channel type MISFET is extended by forming the channel layer of SiGe grown by epitaxial growth, so that tensile stresses in the channel orientation and in the gate width direction are applied to the channel region of the n-channel type MISFET has been known. However, this method has a shortcoming of increasing the complexity of the fabrication process steps, compared to known fabrication process steps (see Low Power Device Technology with SiGe Channel, HfSiON, and Poly-Si Gate, Howard C.-H, Wang et al, 2004 IEDM Tech. Dig).

FIG. 12 is a schematic view illustrating an n-channel type MISFET with a <100> channel orientation (which means that the channel orientation thereof is a <100> orientation). In FIG. 12, stress orientations which improve the mobility of carriers are also shown. As shown in FIG. 12, in the case of the n-channel type MISFET with the <100> channel orientation, out of stresses applied to a channel, a tensile stress applied in the channel orientation, a compressive stress applied in the gate width direction and a compressive stress in the substrate normal direction improve the mobility of carriers. The orientations of stresses applied in the gate width direction which improve the mobility are different from those in FIG. 11. Moreover, in a p-channel type MISFET with a <100> channel orientation, a stress applied to a channel does not largely affect the mobility of carriers.

FIGS. 13A and 13B are views illustrating a known n-channel type MISFET. FIG. 13A is a plan view of the known n-channel type MISFET and FIG. 13B is a cross-sectional view taken along the line X-X of FIG. 13A.

The n-channel type MISFET of FIG. 13 includes a substrate 101 having a p-type semiconductor region, a STI (shallow trench isolation) 103 formed in the substrate 101, an active region 102 formed in part of the substrate 101 surrounded by the SIT 103, a gate insulation film 104 formed on the active region 102, a gate electrode 105 formed on the gate insulation film 104 and source/drain regions 106 formed in parts of the active region 102 located on both sides of the gate electrode 105, respectively. As shown in FIG. 13, using a relatively easy method in which an impurity which does not directly affect the generation of carriers is uniformly and entirely doped into the gate electrode 105 formed over the STI 103 and the active region 102, an intra-film compressive stress 107 is generated throughout the gate electrode 105. The intra-film compressive stress 107 generated in the gate electrode 105 has the readiness to release compressive stresses out, so that a tensile stress toward the outside is generated. Therefore, a method in which a compress stress 108 in the substrate normal direction is applied to the channel region of the substrate 101 through the gate insulation film 104 and a tensile stress is applied in the channel orientation and the gate width direction has been known (see Gate stack optimization for 65 nm CMOS Low Power and High Performance platform, B. Duriezl et al., 2004 IEDM Tech. Dig.).

### SUMMARY OF THE INVENTION

However, the known fabrication method has a problem in which a large amount of an impurity which does not directly affect the generation of carries is doped into a gate electrode on a channel region, so that a gate insulation film is degraded.

It is therefore an object of the present invention to provide a semiconductor device including a MISFET in which the mobility of carriers is improved without degrading a gate insulation film and a method for fabricating the semiconductor device.

To achieve the above-described object, a first semiconductor device according to the present invention includes an isolation region formed in a substrate, an active region formed in part of the substrate surrounded by the isolation region, a gate insulation film formed on the active region, a gate electrode formed on the gate insulation film so as to extend onto the isolation region and impurity doped regions formed in parts of the active region located on both sides of the gate electrode, respectively, and containing a first impurity having a conductivity type. In the first semiconductor device, the gate electrode includes first part located on the isolation region and second part located on the active region, and the first part of the gate electrode includes a larger stress than a stress in the second part of the gate electrode.

With this structure, it is possible to make the first part of the gate electrode located on the isolation region arbitrarily include a compressive stress or a tensile stress. Accordingly, a stress in the direction which allows improvement of the mobility of carries according to a conductivity type of a MISFET can be applied to a channel region. Moreover, the first part of the gate electrode is located on the isolation region and thus does not affect the gate insulation film. Therefore, the intensity of the stress in the first part can be arbitrarily set.

In the first semiconductor device, the first part of the gate electrode may contain a second impurity which changes a lattice constant of the gate electrode.

In this structure, the first part of the gate electrode is located on the isolation region, and thus even if the second impurity is introduced at a high concentration, the gate insulation film is not degraded. Therefore, a large stress can be applied to a channel without concern for quality degradation.

In the first semiconductor device, the second part of the gate electrode may contain the second impurity at a lower concentration than a concentration of the second impurity in the first part.

In the first semiconductor device, the second impurity may be an impurity which does not have a conductivity type.

In the first semiconductor device, the first impurity may be an n-type impurity, and the second impurity may be an impurity which increases the lattice constant of the gate electrode.

In the first semiconductor device, the gate electrode may be formed of polysilicon, and the second impurity may be germanium.

In the first semiconductor device, the first impurity may be an n-type impurity, and the second impurity may be an impurity having the same conductivity type as the conductivity type of the first impurity.

In the first semiconductor device, the first impurity may be a p-type impurity, and the second impurity may be an impurity which reduces the lattice constant of the gate electrode.

In the first semiconductor device, the gate electrode may be formed of polysilicon, and the second impurity may be carbon.

A second semiconductor device according to the present invention includes a substrate including an active region formed therein, an isolation region formed in the substrate so as to surround the active region, a gate insulation film formed on the active region, a gate electrode provided on the gate insulation film, impurity doped regions formed in parts of the active region located on both sides of the gate electrode, respectively, and containing a first impurity having a conductivity type, and a dummy gate electrode provided over the substrate so as to face the gate electrode with an associated one of the impurity doped regions interposed between the dummy gate electrode and the gate electrode and containing a second impurity which changes an intrinsic lattice constant of a material forming the dummy gate electrode.

With this structure, it is possible to make the dummy gate electrode arbitrarily include a compressive stress or a tensile stress. Accordingly, a stress in the direction which allows improvement of the mobility of carriers according to a conductivity type of a MISFET can be applied to a channel region. Moreover, the dummy gate electrode is provided so as to be apart from the gate insulation film of the MISFET and thus the second impurity can be introduced into the dummy gate electrode at a higher concentration than in the case where an impurity is introduced into the gate electrode. Therefore, a larger stress can be applied to a channel region of the MISFET, so that the mobility of carriers can be further improved.

A first method for fabricating a semiconductor device according to the present invention includes the steps of a) forming an isolation region in a substrate, b) forming a gate insulation film on an active region formed in part of the substrate surrounded by the isolation region, c) forming a gate electrode on the gate insulation film so as to extend onto the isolation region, d) making first part of the gate electrode located on the isolation region contain a larger stress than a stress in second part of the gate electrode located on the active region, and e) forming impurity doped regions in parts of the active region located on both sides of the gate electrode, respectively, each of the impurity regions containing a first impurity having a conductivity type.

According to this method, it is possible to make the first part of the gate electrode located on the isolation region arbitrarily include a compressive stress or a tensile stress. Accordingly, a MISFET in which a stress in the direction which allows improvement of the mobility of carries according to a conductivity type of a MISFET is applied to a channel region can be fabricated.

In the first method for fabricating a semiconductor device, in the step d), a second impurity which changes a lattice constant of the gate electrode may be selectively implanted into the first part of the gate electrode, thereby making the first part include a larger stress than a stress in the second part of the gate electrode.

In the first method for fabricating a semiconductor device, in the step c), the second impurity may be implanted into the gate electrode patterned at a smaller dose than a dose of the second impurity to be implanted in the step d).

In the first method for fabricating a semiconductor device, the second impurity may be an impurity which does not have a conductivity type.

In the first method for fabricating a semiconductor device, the first impurity may be an n-type impurity, and the second impurity may be an impurity which increases a lattice constant of the gate electrode.

In the first method for fabricating a semiconductor device, the first impurity may be a p-type impurity, and the second impurity may be an impurity which reduces a lattice constant of the gate electrode.

A second method for fabricating a semiconductor device according to the present invention includes the steps of a) forming, in a substrate including an active region formed therein, an isolation region so as surround the active region, b) forming a gate insulation film and a gate electrode over the active region, c) forming, at least in part of the substrate located over the active region and on a side of the gate electrode, a dummy gate electrode containing a first impurity which changes an intrinsic lattice constant of a material forming the dummy gate electrode, and d) forming impurity doped regions each containing a second impurity having a conductivity type in parts of the active region located on both sides of the gate electrode, respectively, each of the parts being located between the gate electrode and the dummy gate electrode.

According to this method, it is possible to make the dummy gate electrode arbitrarily include a compressive stress or a tensile stress. Accordingly, a stress in the direction which allows improvement of the mobility of carries according to a conductivity type of a MISFET can be applied to a channel region. Moreover, the dummy gate electrode is provided so as to be apart from the gate insulation film of the MISFET and thus the second impurity can be introduced into the dummy gate electrode at a higher concentration than in the case where an impurity is introduced into the gate electrode.

### BRIEF DESCRIPTION OF THE DRAWINGS

FIGS. 1A through 1C are view illustrating an n-channel type MISFET according to a first embodiment of the present invention. FIG. 1A is a plan view of the n-channel type MISFET. FIG. 1B is a cross-sectional view taken along the line A-A of FIG. 1A. FIG. 1C is a perspective view of the n-channel type MISFET.

FIGS. 2A through 2C are views illustrating a p-channel type MISFET according to a second embodiment of the present invention. FIG. 2A is a plan view of the p-channel type MISFET. FIG. 2B is a cross-sectional view taken along the line B-B of FIG. 2A. FIG. 2C is a perspective view of the p-channel type MISFET.

FIGS. 3A through 3C are views illustrating an n-channel type MISFET according to a third embodiment of the present invention. FIG. 3A is a plan view of the n-channel type MISFET. FIG. 3B is a cross-sectional view taken along the line C-C of FIG. 3A. FIG. 3C is a perspective view of the n-channel type MISFET.

FIGS. 4A through 4D are cross-sectional views illustrating respective steps of a method for fabricating a semiconductor device according to a fourth embodiment of the present invention.

FIGS. 5A through 5D are cross-sectional views illustrating respective steps of a method for fabricating a semiconductor device according to a fifth embodiment of the present invention.

FIGS. 6A through 6C are views illustrating an n-channel type MISFET according to a sixth embodiment of the present invention. FIG. 6A is a plan view of the n-channel type MISFET. FIG. 6B is a cross-sectional view taken along the line C-C of FIG. 6A. FIG. 6C is a perspective view of the n-channel type MISFET.

FIGS. 7A through 7E are cross-sectional views illustrating respective steps of a method for fabricating a semiconductor device according to a seventh embodiment of the present invention.

FIGS. 8A through 8E are cross-sectional views illustrating respective steps of a method for fabricating a semiconductor device according to a first modified example of the seventh embodiment.

FIGS. 9A through 9E are cross-sectional views illustrating respective steps of a method for fabricating a semiconductor device according to a second modified example of the seventh embodiment.

FIGS. 10A through 10C are cross-sectional views illustrating respective steps of a method for fabricating a semiconductor device according to an eighth embodiment of the present invention.

FIG. 11A is a perspective view illustrating orientations and types of stresses which improve the mobility of carriers in an n-channel type MISFET. FIG. 11B is a schematic view illustrating orientations and types of stresses which improve the mobility of carriers in a p-channel type MISFET.

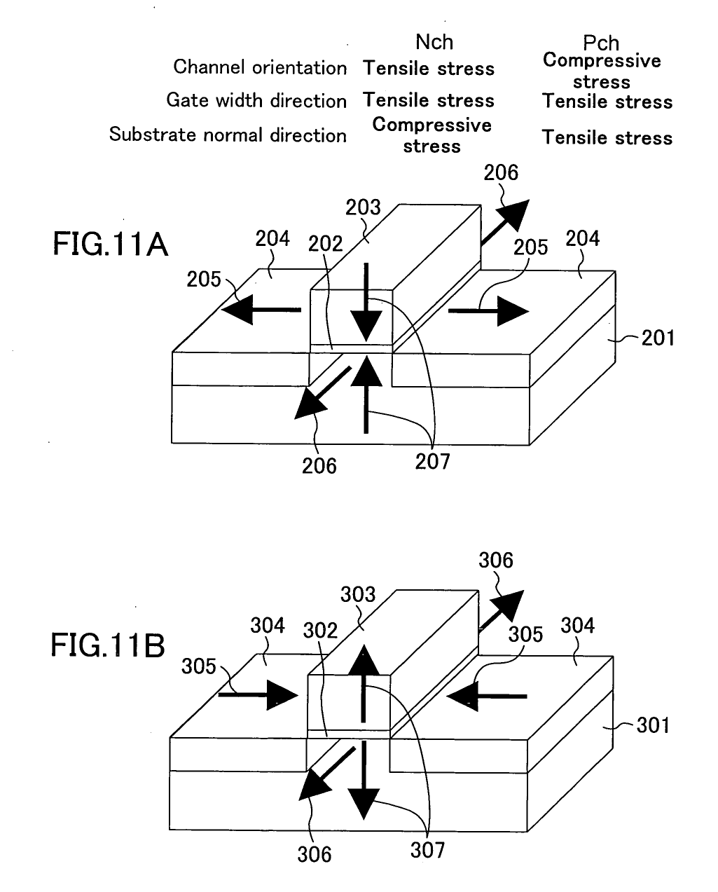

FIG. 12 is a schematic view illustrating an n-channel type MISFET fabricated using a silicon substrate with a principal surface of a <100> plane.

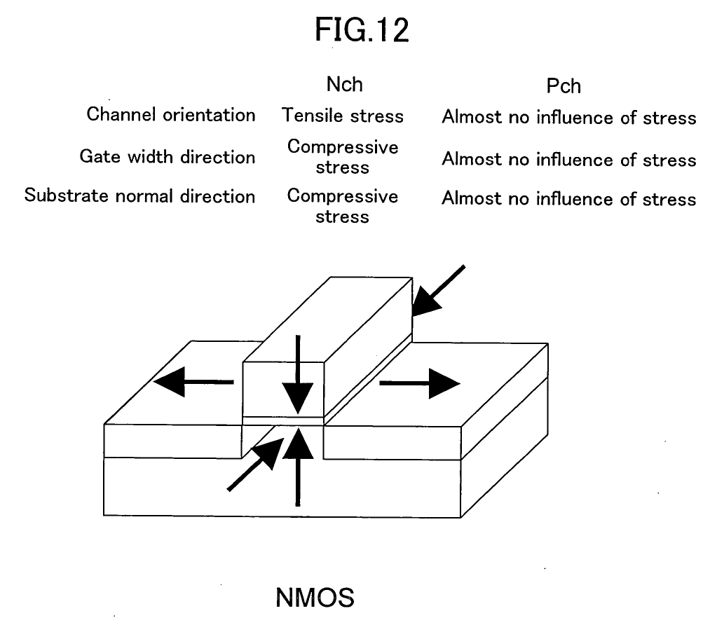

FIGS. 13A and 13B are views illustrating a known n-channel type MISFET. FIG. 13A is a plan view of the known n-channel type MISFET. FIG. 13B is a cross-sectional view taken along the line X-X of FIG. 13A.

### DESCRIPTION OF THE PREFERRED EMBODIMENTS

### First Embodiment

Hereafter, a semiconductor device including an n-channel type MISFET according to a first embodiment of the present invention will be described with the accompanying drawings.

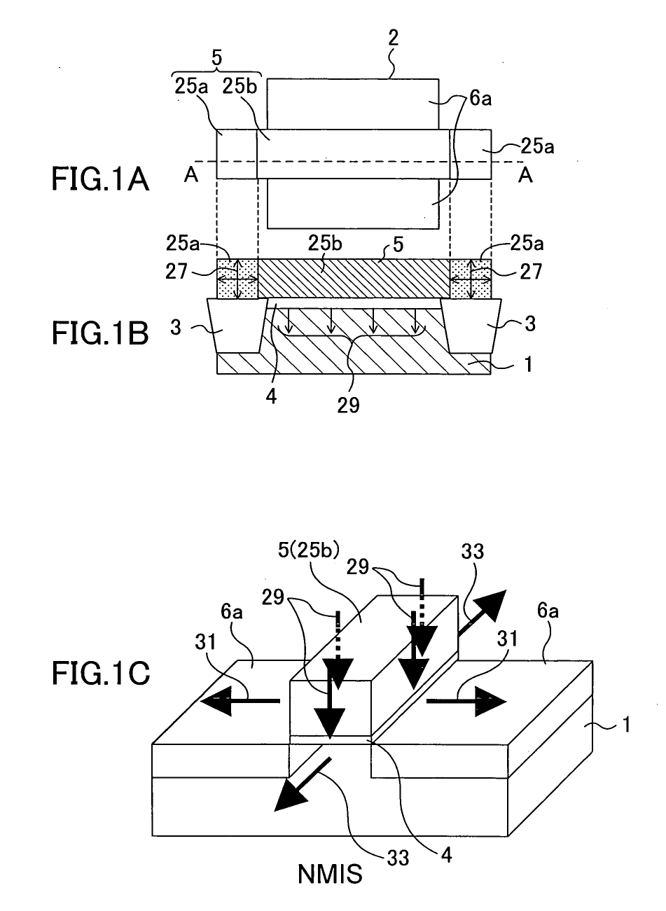

FIGS. 1A through 1C are view illustrating the n-channel type MISFET according to the first embodiment of the present invention. FIG. 1A is a plan view of the n-channel type MISFET. FIG. 1B is a cross-sectional view taken along the line A-A of FIG. 1A. FIG. 1C is a perspective view of the n-channel type MISFET.

The n-channel type MISFET of FIG. 1 includes a substrate 1 having a p-type semiconductor region (not shown), an isolation region 3 formed of a STI in the substrate 1, an active region 2 formed in part of the substrate 1 surrounded by the isolation region 3, a gate insulation film 4 provided on the active region 2, a gate electrode 5 provided on the gate insulation film 4 so as to extend onto the isolation region 3, and impurity doped regions (source/drain regions) 6a provided in parts of the active region 2 located on both sides of the gate electrode 5, respectively, and containing an n-type impurity. The impurity doped regions 6a may be LDD regions or extension regions.

The gate electrode 5 is formed of, for example, polysilicon containing an n-type impurity. The substrate 1 is formed of semiconductor such as silicon. Germanium (Ge), tin (Sn) or the like which has a larger lattice constant than that of a material (silicon) forming the gate electrode 5 and does not affect the generation of carries is introduced into part 25a of the gate electrode 5 located on the isolation region 3. Ge is not introduced into part 25b of the gate electrode 5 located on the active region 2.

The gate insulation film 4 is formed of SiO₂ or some other insulating material and has a thickness of, for example, about 2 nm. The gate insulation film 4 has a very small thickness and thus gives a stress in the substrate normal direction as it is from the gate electrode 5 to a channel region.

In the n-channel type MISFET of this embodiment, as described above, Ge, Sn or the like is introduced as a material which increases a lattice constant into the part 25a of the gate electrode 5 located on the isolation region 3. Thus, as shown in FIGS. 1B and 1C, an intra-film compressive stress 27 is generated in the part 25a of the gate electrode 5 in which Ge, Sn or the like has been introduced. The part 25a including the intra-film compressive stress 27 gives a compressive stress to the isolation region 3, the part 25b (in which a material which increases a lattice constant is not introduced) of the gate electrode 5 located on the active region 2 and the like. The part 25b of the gate electrode 5 is distorted by application of the compressive stress from the part 25a located at each of the both sides of the part 25b of the gate electrode 5 and gives a compressive stress 29 in the substrate normal direction to a channel region. With the compressive stress 29, the mobility of carriers in the n-channel type MISFET of this embodiment is largely improved. The above-described channel region is part of the substrate 1 interposed between the two impurity doped regions (source/drain regions) 6a and located immediately under the gate electrode 5.

As shown in FIG. 1C, when the compressive stress 29 is applied to the channel region, a tensile stress 31 in the channel orientation and a tensile stress 33 in the gate width direction are generated in the channel region. In a MISFET with a <110> channel orientation, each of the tensile stresses 31 and 33 improves the mobility of carriers in the n-channel type MISFET. Accordingly, in the MISFET of this embodiment, a very large mobility can be achieved. On the other hand, in a MSIFET with a <100> channel orientation, the tensile stress 31 can improve the mobility of carriers.

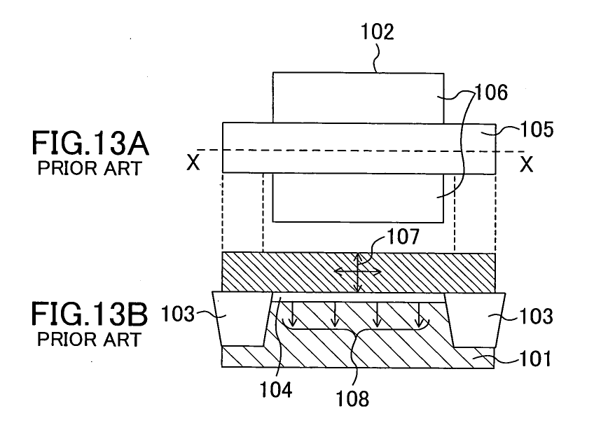

Furthermore, in the n-channel type MISFET of this embodiment, an impurity such as Ge and Sn which changes a lattice constant is not introduced in the part 25b of the gate electrode 5 located immediately on the gate insulation film 4. Thus, in the n-channel type MISFET of this embodiment, degradation of a gate insulation film which becomes a problem when Ge is introduced in an entire gate electrode as shown in FIG. 13 is not caused. Moreover, the concentration of the impurity such as Ge and Sn contained in the part 25a of the electrode 5 located on the isolation region 3 can be increased without concern for degradation of the gate insulation film 4. Therefore, the larger compressive stress 29 can be applied to the channel region.

An impurity such as Ge and Sn can be selectively introduced into only the part 25a of the gate electrode 5, for example, by ion implantation. When Ge is implanted into the gate electrode of polysilicon, ion implantation can be performed, for example, at a dose of 1×10¹⁵ cm⁻² or more.

The impurity introduced into the part 25a of the gate electrode 5 is not limited to Ge and Sn. Any other materials which can increase the lattice constant of the gate electrode 5 may be used. Specifically, a material of the same family as that of a material of the gate electrode in the periodic table does not affect the generation of carriers and thus is preferable.

### Second Embodiment

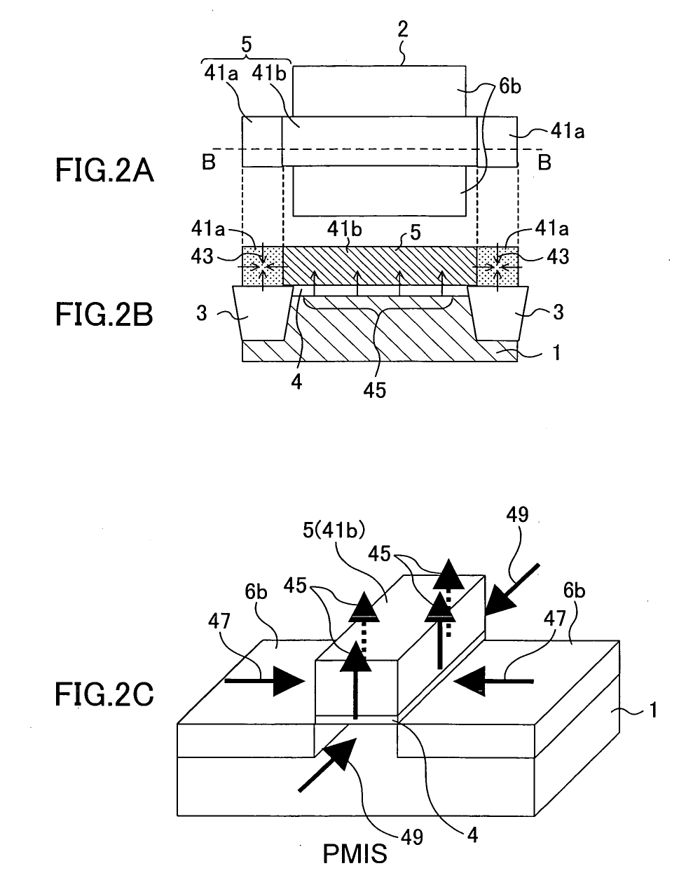

FIGS. 2A through 2C are views illustrating a p-channel type MISFET according to a second embodiment of the present invention. FIG. 2A is a plan view of the p-channel type MISFET. FIG. 2B is a cross-sectional view taken along the line B-B of FIG. 2A. FIG. 2C is a perspective view of the p-channel type MISFET.

The p-channel type MISFET of FIG. 2 includes a substrate 1 having an n-type semiconductor region (now shown), an isolation region 3 formed of a STI in the substrate 1, an active region 2 formed in part of the substrate 1 surrounded by the isolation region 3, a gate insulation film 4 provided on the active region 2, a gate electrode 5 provided on the gate insulation film 4 so as to extend onto the isolation region 3, and impurity doped regions (source/drain regions) 6b provided in parts of the active region 2 located on both sides of the gate electrode 5, respectively, and containing a p-type impurity. The impurity doped regions 6b may be LDD regions or extension regions.

The gate electrode 5 is formed of, for example, polysilicon containing a p-type impurity. The substrate 1 is formed of semiconductor such as silicon. Carbon (C) which has a smaller lattice constant than that of a material (silicon) forming the gate electrode 5 and does not affect the generation of carries is introduced into part 41a of the gate electrode 5 located on the isolation region 3. Carbon is not introduced into part 41b of the gate electrode 5 located on the active region 2.

In the p-channel type MISFET of this embodiment, as described above, carbon is introduced as a material which reduces a lattice constant into the part 41a of the gate electrode 5 located on the isolation region 3. Thus, as shown in FIGS. 2B and 2C, an intra-film tensile stress 43 is generated in the part 41a of the gate electrode 5. The part 41a including the intra-film tensile stress 43 gives a tensile stress to the isolation region 3, the part 41b (in which a material which reduces the lattice constant of the part 41b is not introduced) of the gate electrode 5 located on the active region 2 and the like. The part 41b of the gate electrode 5 is distorted by application of the tensile stress from the part 41a located at each of the both sides of the part 41b of the gate electrode 5 and gives a tensile stress 45 in the substrate normal direction to a channel region. For example, in a MISFET with a <110> channel orientation, due to the tensile stress 45, the mobility of carriers in the p-channel type MISFET of this embodiment is largely improved.

As shown in FIG. 2C, when the tensile stress 45 is applied to the channel region, a compressive stress 47 in the channel orientation and a compressive stress 49 in the gate width direction are generated in the channel region. Of the two compressive stresses, the compressive stress 47 in the channel orientation contributes to improvement of the mobility of carriers. Accordingly, in the p-channel type MISFET of this embodiment, the mobility of carriers can be largely improved, compared to a p-channel type MISFET where a stress is not applied to a channel region.

Furthermore, in the p-channel type MISFET of this embodiment, an impurity such as carbon which changes a lattice constant is not introduced in the part 41b of the gate electrode 5 located immediately on the gate insulation film 4. Thus, in the p-channel type MISFET of this embodiment, degradation of a gate insulation film which becomes a problem when carbon is introduced in an entire gate electrode is not caused. Moreover, the concentration of the impurity such as carbon contained in the part 41a of the electrode 5 located on the isolation region 3 can be increased without concern for degradation of the gate insulation film 4. Therefore, the larger tensile stress 45 can be applied to the channel region.

An impurity such as carbon can be selectively introduced into only the part 41a of the gate electrode 5, for example, by ion implantation. When carbon is implanted into the gate electrode of polysilicon, ion implantation can be performed, for example, at a dose of 1×10¹⁵ cm⁻² or more.

The impurity introduced into the part 41a of the gate electrode 5 is not limited to carbon. Any other materials which can reduce the lattice constant of the gate electrode 5 may be used. Specifically, a material of the same family as that of a material of the gate electrode in the periodic table does not affect the generation of carriers and thus is preferable.

### Third Embodiment

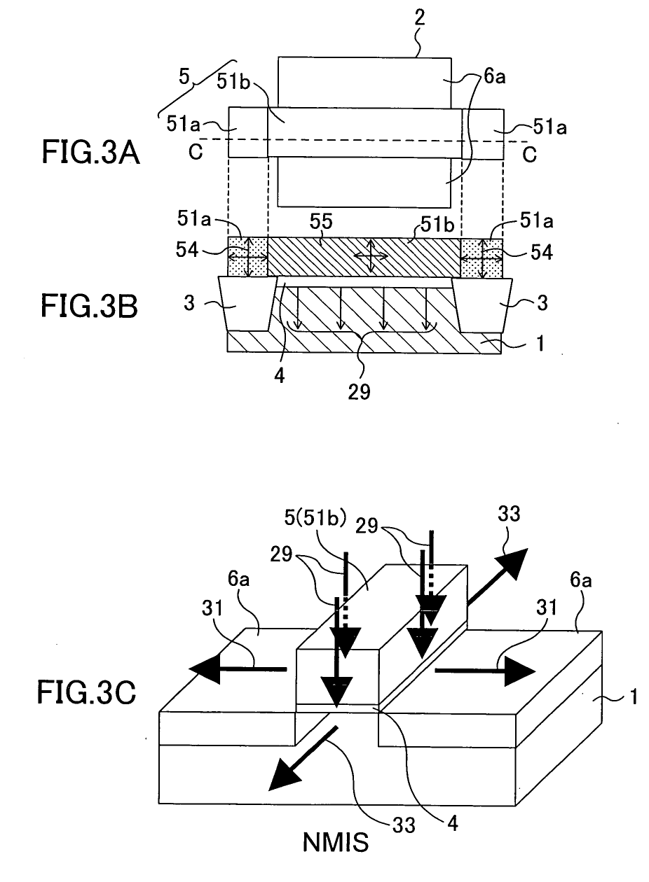

FIGS. 3A through 3C are views illustrating an n-channel type MISFET according to a third embodiment of the present invention. FIG. 3A is a plan view of the n-channel type MISFET. FIG. 3B is a cross-sectional view taken along the line C-C of FIG. 3A. FIG. 3C is a perspective view of the n-channel type MISFET.

As shown in FIGS. 3A through 3C, the n-channel type MISFET of this embodiment includes a substrate 1 having a p-type semiconductor region (now shown), an isolation region 3 formed of a STI in the substrate 1, an active region 2 formed in part of the substrate 1 surrounded by the isolation region 3, a gate insulation film 4 provided on the active region 2, a gate electrode 5 provided on the gate insulation film 4 so as to extend onto the isolation region 3, and impurity doped regions 6a provided in parts of the active region 2 located on both sides of the gate electrode 5, respectively, and containing an n-type impurity.

Ge, Sn or the like which has a larger lattice constant than that of a material (silicon) forming the gate electrode 5 and does not affect the generation of carries is introduced into part 51a of the gate electrode 5 located on the isolation region 3. Unlike the n-channel type MISFET of the first embodiment, an impurity such as Ge and Sn is introduced into part 51b of the gate electrode 5 located on the active region 2 at a lower concentration than a concentration of the impurity introduced in the part 51a. Thus, a large intra-film compressive stress 54 is generated in the part 51a of the gate electrode 5. A smaller intra-film compressive stress 55 is generated in the part 51b than in the part 51a. Accordingly, with the intra-film compressive stress 54 in the part 51a and the intra-film compressive stress 55 in the part 51b generated in the gate electrode 5, a compressive stress 29 in the substrate normal direction is applied to a channel region. In a structure of this embodiment, compared to a structure of the first embodiment shown in FIGS. 1A through 1C, the intra-film compressive stress 55 in the part 51b of the gate electrode 5 is further added, so that the large compressive stress 29 can be applied. As shown in FIG. 3C, in the channel region, a tensile stress 31 in the channel orientation and a tensile stress 33 in the gate width direction are generated by the compressive stress 29. In an n-channel type MISFET with a <110> channel orientation, each of the compressive stress 29 and the tensile stresses 31 and 33 improves the mobility of carriers in the n-channel type MISFET. Therefore, in the n-channel type MISFET of this embodiment, the mobility of carriers is very large, compared to the case where a stress is not applied to the channel region.

An impurity which increases a lattice constant is introduced into the part 51b of the gate electrode 5 located on the active region 2 at an amount which does not cause degradation of the gate insulation film 4. When Ge is introduced into the part 51b by ion implantation, it is preferable that implantation is performed, for example, at a dose of 1×10¹⁴ cm⁻² or less. On the other hand, Ge is ion-implanted into the part 51a of the gate electrode 5 provided on the isolation region 3 at a dose of about 1×10¹⁵ cm⁻² which is increased by an order magnitude from the dose of ion-implantation to the part 51b.

Although there are slight differences among materials, it is considered that if an impurity which changes a lattice constant of a gate electrode is ion-implanted at a dose of 1×10¹⁵ cm⁻² or less, an insulation film is not degraded. The n-channel type MISFET of this embodiment is formed using ion implantation of Ge or like impurity at a dose of 1×10¹⁵ cm⁻² or less. Thus, the mobility of carriers is improved and, at the same time, degradation of the gate insulation film 4 is prevented.

In a surface channel transistor in which carriers travel in part of a substrate located in the vicinity of an interface with a gate insulation film or a buried channel transistor in which a channel is buried in a substrate, a donor (n-type impurity) or an acceptor (p-type impurity) has to be introduced to a gate electrode. When introducing a donor or an acceptor into a gate electrode, the magnitude of a stress to be applied to a channel region can be adjusted by adjusting amount and type of the donor or the acceptor. Specifically, when the gate electrode 5 is formed of n⁺Si, the concentration of phosphorus (P) is increased and the concentration of arsenic (As) is reduced in the part 51b provided on the active region 2. Since As has a larger lattice constant than the lattice constant of Si, as in the case of Ge, introduction of As into the gate electrode 5 can increase the lattice constant of the part of the gate electrode 5 into which As is introduced. On the other hand, a method in which the As concentration is increased and the P concentration is reduced in the part 51a of the gate electrode 5 located on the isolation region 3 can be also used. In this manner, a method for adjusting amount and type of an impurity serving as an acceptor or a donor may be used with a method for mixing an element which can increase a lattice constant.

### Fourth Embodiment

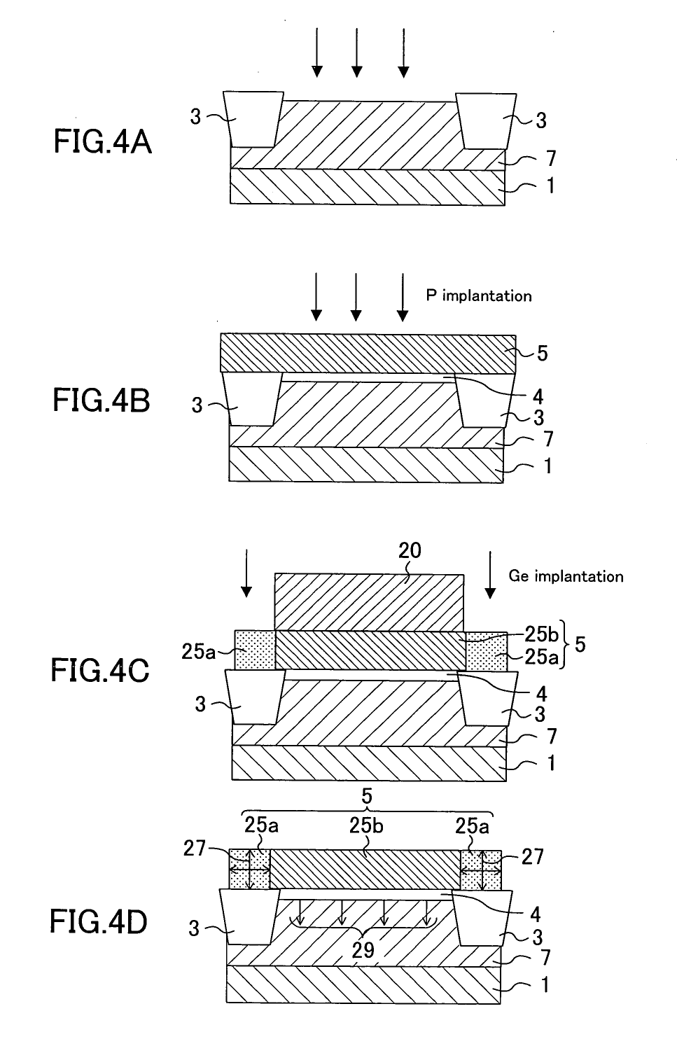

As a fourth embodiment of the present invention, a method for fabricating an n-channel type MISFET according to the first embodiment will be described. FIGS. 4A through 4D are cross-sectional views illustrating respective steps of a method for fabricating a semiconductor device according to the fourth embodiment.

First, as shown in FIG. 4A, a p-type impurity such as boron (B) is ion-implanted into a substrate 1 of a p-type semiconductor substrate (or a p-type semiconductor layer formed on the substrate 1) to form a p-type well 7 in the substrate 1. In this case, ion implantation is performed at an implantation energy of 300 keV and a dose of 1×10¹³ cm⁻². Next, a p-type impurity (such as B) is ion-implanted into part of the p-type well 7 at an implantation energy of 150 keV and a dose of 1×10¹³ cm⁻², thereby forming a punch through stopper. Moreover, a p-type impurity (such as B) is implanted into part of the substrate 1 which is to be a channel region at an implantation energy of 20 keV and a dose of 5×10¹² cm⁻². Next, an isolation region 3 is formed of an STI in the substrate 1 (p-type well 7) by a known method so as to surround an isolation region 2 (shown in FIG. 1A) formed in part of the substrate 1.

Next, as shown in FIG. 4B, a gate insulation film 4 is formed over the substrate 1 (p-type well 7) by thermal oxidation so as to have a thickness of 2 nm and then a polysilicon film is formed on the isolation region 3 and the gate simulation film 4 so as to have a thickness of 150 nm. Thereafter, P is ion-implanted into the polysilicon film at an implantation energy of 10 keV and a dose of 5×10¹⁵ cm⁻². Subsequently, the polysilicon film is patterned by etching using a resist, thereby forming a gate electrode 5 on the gate insulation film 4 so as to extend onto the isolation region 3.

Next, as shown in FIG. 4C, a resist 20 is formed on the substrate 1 so as to have an opening corresponding to part 25a of the gate electrode 5 located immediately on the isolation region 3 and cover part 25b of the gate electrode 5 located immediately on the active region 2. Thereafter, using the resist 20 as a mask, Ge is implanted into the part 25a of the gate electrode 5 at an implantation energy of 200 keV and a dose of 1×10¹⁵ cm⁻². In forming the resist 20 to be used for ion implantation of Ge, in order to obtain a margin for resist alignment, part of the isolation region 3 inwardly extending from an end of the active region to a certain extent is covered by the resist. Thus, a structure in which even if there is an error in resist alignment, Ge is not implanted to the active region 2 can be achieved. In this manner, Ge can be implanted at relatively high energy.

Next, as shown in FIG. 4D, As, which is an n-type impurity, is ion-implanted into parts of the active region 2 in the substrate 1 located on both sides of the gate electrode 5, respectively, at an implantation energy of 30 keV and a dose of 5×10¹⁵ cm⁻², thereby forming n-type impurity dopes regions (the n-type impurity doped regions 6a of FIGS. 1A and 1C). The n-type impurity doped regions serve as LDD regions, extension regions, or source/drain regions.

In the above-described manner, the n-channel type MISFET of the first embodiment can be fabricated in a relatively simple manner.

In the step of performing ion implantation shown in FIG. 4C, implantation of Ge may be performed for several times at a plurality of different energy conditions to achieve a uniform impurity distribution of Ge in the part 25a. Also, even if, instead of Ge, As or Sn is implanted, an intra-film compressive stress 27 can be generated. A combination of at least two of the As implantation, the Ge implantation and the Sn implantation may be used. In this embodiment, implantation of Ge into the part 25a of the gate electrode 5 is performed after the polysilicon film has been patterned. However, Ge may be implanted into the part 25a before patterning of the polysilicon film. For example, Ge may be implanted right after the polysilicon film is formed or after P is implanted into the polysilicon film.

### Fifth Embodiment

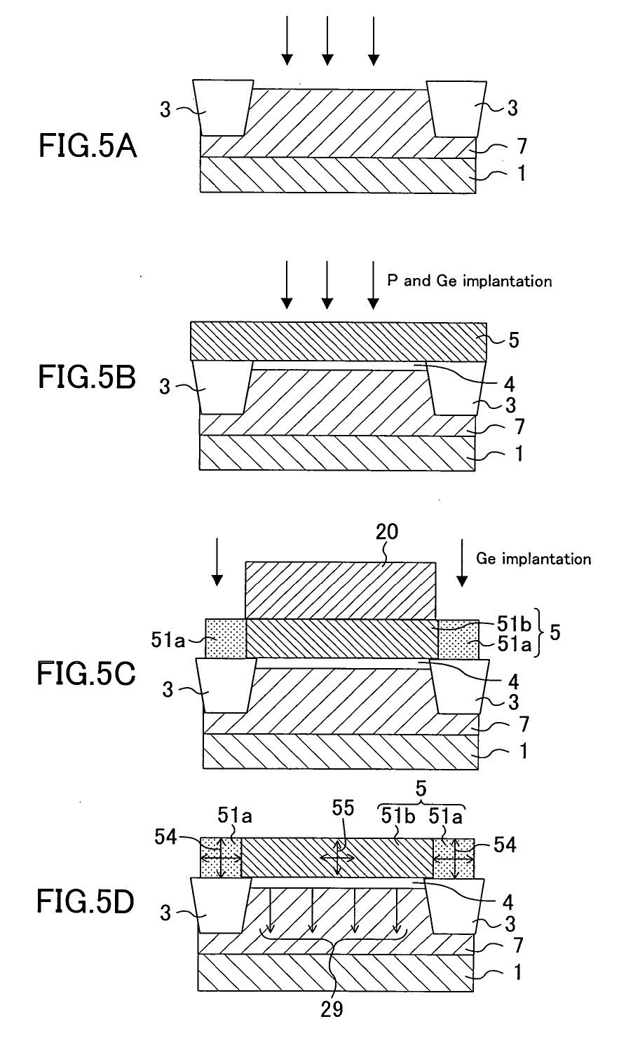

As a fifth embodiment of the present invention, a method for fabricating an n-type channel MISFET according to the third embodiment will be described. FIGS. 5A through 5D are cross-sectional views illustrating respective steps of a method for fabricating an n-channel type MISFET according to the fifth embodiment.

First, as shown in FIG. 5A, as in the fourth embodiment, a p-type well 7, an isolation region 3 and a punch through stopper are formed in a substrate 1, and then B is implanted to a channel region.

Next, as shown in FIG. 5B, a gate insulation film 4 is formed over the substrate 1 (p-type well 7) by thermal oxidation so as to have a thickness of 2 nm and then a polysilicon film is formed on the isolation region 3 and the gate simulation film 4 so as to have a thickness of 150 nm. Thereafter, P is ion-implanted into the polysilicon film at an implantation energy of 10 keV and a dose of 5×10¹⁵ cm⁻². Subsequently, Ge is implanted into the polysilicon film at an implantation energy of 100 keV and a dose of 1×10¹⁴ cm⁻². Then, the polysilicon film is patterned by etching using a resist, thereby forming a gate electrode 5.

Next, as shown in FIG. 5C, a resist 20 is formed on the substrate 1 so as to have an opening corresponding to part 51a of the gate electrode 5 located immediately on the isolation region 3 and cover part 51b of the gate electrode 5 located immediately on the active region 2. Thereafter, using the resist 20 as a mask, Ge is implanted into the part 51a of the gate electrode 5 at an implantation energy of 200 keV and a dose of 1×10¹⁵ cm⁻². Thus, a small intra-film compressive stress 55 is generated in the part 51b of the gate electrode 5 which contains Ge at a low concentration, and a large intra-film compressive stress 54 is generated in the part 51a of the gate electrode 5 which contains Ge at a high concentration. Due to actions of the intra-film compressive stress 55 and the intra-film compressive stress 54, a compressive stress 29 in the substrate normal direction is applied to the channel region.

Next, as shown in FIG. 5D, As which is an n-type impurity, is ion-implanted into parts of the active region 2 in the substrate 1 located on both sides of the gate electrode 5, respectively, at an implantation energy 30 keV and a dose of 5×10¹⁵ cm⁻², thereby forming n-type impurity dopes regions (the n-type impurity doped regions 6a of FIGS. 3A and 3C). The n-type impurity doped regions serve as LDD regions, extension regions, or source/drain regions.

In the above-described manner, the n-channel type MISFET of the third embodiment can be fabricated in a relatively simple manner.

In the step shown in FIG. 5C, instead of Ge, As or Sn may be implanted. Also, a combination of at least two of the As implantation, the Ge implantation and the Sn implantation may be used.

In this embodiment, implantation of Ge into the part 51a of the gate electrode 5 is performed after the polysilicon film has been patterned. However, Ge may be implanted into the part 51a before patterning of the polysilicon film. For example, Ge may be implanted right after the polysilicon film is formed or after P is implanted into the polysilicon film.

### Sixth Embodiment

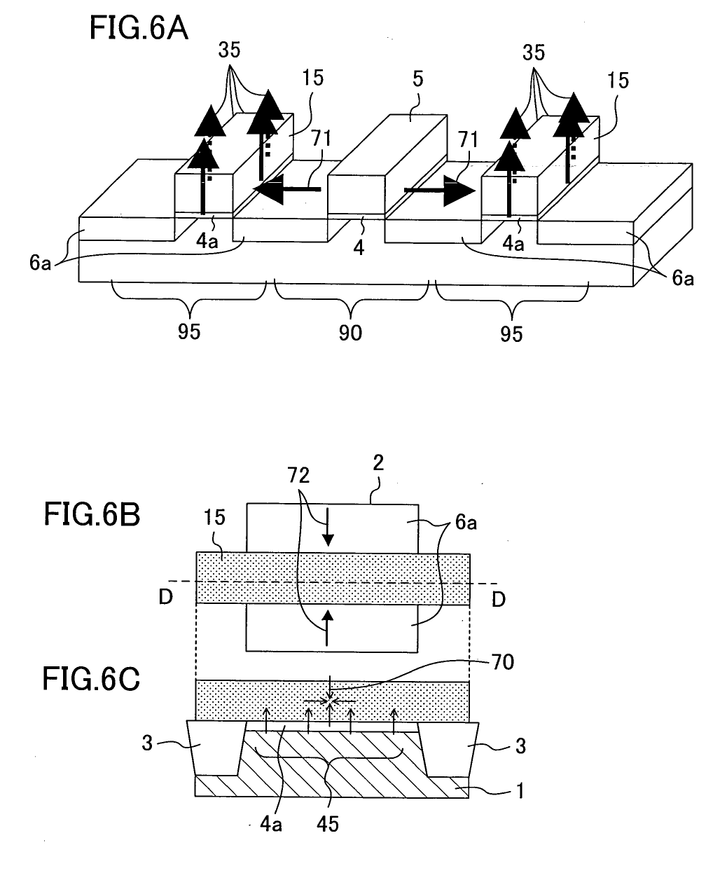

FIG. 6A is a perspective view illustrating a semiconductor device according to a sixth embodiment of the present invention. FIG. 6B is a plan view illustrating a dummy transistor of the semiconductor device of this embodiment. FIG. 6C is a cross-sectional view taken along the line D-D. The semiconductor device of this embodiment includes dummy gate electrodes provided so that each of the dummy gate electrodes faces a gate electrode and contains an impurity which changes a lattice constant.

As shown in FIGS. 6A through 6C, the semiconductor device of this embodiment includes an n-channel type MISFET 90 and dummy gate electrodes 15 each of which is provided so as to be located adjacent to the MISFET 90. In an example shown in FIGS. 6A through 6C, dummy transistors 95 are provided so as to be located in both sides of the MISFET 90, respectively. The dummy transistors 95 include the dummy gate electrodes 15, respectively. Each of the dummy gate electrodes 15 is located so as to face the gate electrode 5 of the MSIFET 90 with an impurity doped region 6a interposed therebetween.

Specifically, the semiconductor device of this embodiment includes an isolation region 3 formed of a STI in a substrate 1 having a p-type semiconductor region (not shown), an active region 2 formed in part of the substrate 1 surrounded by the isolation region 3, a gate insulation film 4 formed on the active region 2, a gate electrode 5 formed on the gate insulation film 4 so as to extend onto the isolation region 3, impurity doped regions (source/drain regions) 6a formed in parts of the active region 2 located on both sides of the gate electrode 5, respectively, and containing an n-type impurity, dummy gate insulation films 4a each having at least part located on the active region 2, and dummy gate electrodes 15 provided so as to extend from dummy gate insulation films 4a, respectively, to the isolation region 3.

Each of the gate electrode 5 and the dummy gate electrodes 15 is formed of, for example, polysilicon containing an n-type impurity or semiconductor such as silicon.

A feature of the semiconductor device of this embodiment is that a material which can reduce a lattice constant of a material forming the dummy gate electrodes 15 and does not affect the generation of carries is introduced into each of the dummy gate electrodes 15. Meanwhile, the material is not introduced into the gate electrode 5. As a material to be introduced into the dummy electrodes 15, for example, carbon (C) is preferably used. However, some other material which satisfies the above-described conditions may be used. Herein, “to reduce a lattice constant of a material forming the dummy gate electrodes 15” means that “to reduce the lattice constant of the dummy gate electrodes 15 to a lower value than that in the case where an impurity is not introduced”.

In the MISFET of this embodiment, a material which can reduce the lattice constant of the dummy gate electrodes 15 is introduced into the dummy gate electrodes 15. Thus, as shown in FIG. 6A, an intra-film tensile stress 70 is generated in each of the dummy gate electrodes 15, and then a tensile stress 45 in the substrate normal direction is applied toward each of the dummy gate electrodes 15. Due to the tensile stress 45, a compressive stress 72 is applied to part of the substrate 1 located under each of the dummy gate electrodes 15. Seen from a different point, the compressive stress 72 is a tensile stress 71 in the channel orientation applied to a channel of the MISFET 90. Accordingly, the mobility of carriers in the n-channel type MISFET 90 is largely improved.

Furthermore, in the semiconductor device of this embodiment, an impurity such as C, which changes a lattice constant is not introduced into the gate electrode 5 of the MISFET 90. Thus, in the semiconductor device of this embodiment, degradation of a gate insulation film which can be a problem when an impurity is introduced into the gate electrode is not caused. Also, compared to the first embodiment in which an impurity is introduced into part of the gate electrode 5 located on the isolation region 3, influences of the impurity to be introduced on the gate insulation film 4 can be reduced. Therefore, the concentration of an impurity such as C contained in the dummy gate electrodes 15 can be increased without concern for degradation of the gate insulation film 4 and a larger tensile stress 71 in the channel orientation can be applied in the channel region.

An impurity such as C can be introduced into the dummy gate electrode 15, for example, by ion implantation. When C is implanted into the dummy gate electrodes 15 of polysilicon, a dose of C can be set to be, for example, 1×10¹⁵ cm⁻² or more.

An impurity to be introduced into the dummy gate electrodes 15 is not limited to C. Any other materials which can increase the lattice constant of the dummy gate electrodes 15 may be used. Specifically, a material of the same family as that of a material of the gate electrode in the periodic table does not affect the generation of carriers and thus is preferable.

Each of the dummy gate insulation films 4a and the dummy gate electrodes 15 only has to have at least part located on the active region 2. Even if each of the dummy gate insulation films 4a and the dummy gate electrodes 15 has part located on the isolation region 3 and the impurity doped regions 6a is formed so that each of the impurity doped regions 6a is located only a side of an associated one of the dummy gate electrodes 15, the tensile stress 71 can be applied to the channel of the MISFET 90.

In FIG. 6, an example in which the dummy gate electrodes 15 are provided in both sides of the MISFET 90, respectively, so that each of the dummy gate electrodes 15 faces the MISFET 90 and extends along the channel orientation (gate length direction) is shown. However, only a single dummy gate electrode 15 may be provided in only one side of the MISFET 90 so as to face the MISFET 90.

In the semiconductor device of this embodiment, a tensile stress in the gate length direction is applied to the channel of the MISFET 90. Thus, the mobility of the MISFET in the <110> channel orientation, the <100> channel orientation and the like can be improved.

In the semiconductor device of this embodiment, an impurity such as C may be introduced only into the dummy gate electrodes 15. However, the impurity may be introduced into parts of the impurity doped regions of the MISFET 90 located in the vicinity of the dummy gate electrodes 15. When an impurity is also introduced into the parts of the impurity doped regions, it is preferable to use an impurity which does not have a conductivity type. In such a case, an intra-film tensile stress is generated in part of the MISFET 90 in which an impurity is introduced and a tensile stress in the channel orientation is applied to the channel of the MISFET 90, so that the mobility of carries can be further improved. As has been described, when C is introduced into the dummy gate electrodes 15, C may be introduced into the parts of the impurity doped regions located in the vicinity of the dummy gate electrodes 15. Accordingly, precise mask alignment becomes unnecessary and thus fabrication process steps are simplified.

In the semiconductor device of this embodiment, an impurity such as Ge and Sn which increases the lattice constant of polysilicon may be further introduced into part of the gate electrode 5 located on the isolation region 3.

### Seventh Embodiment

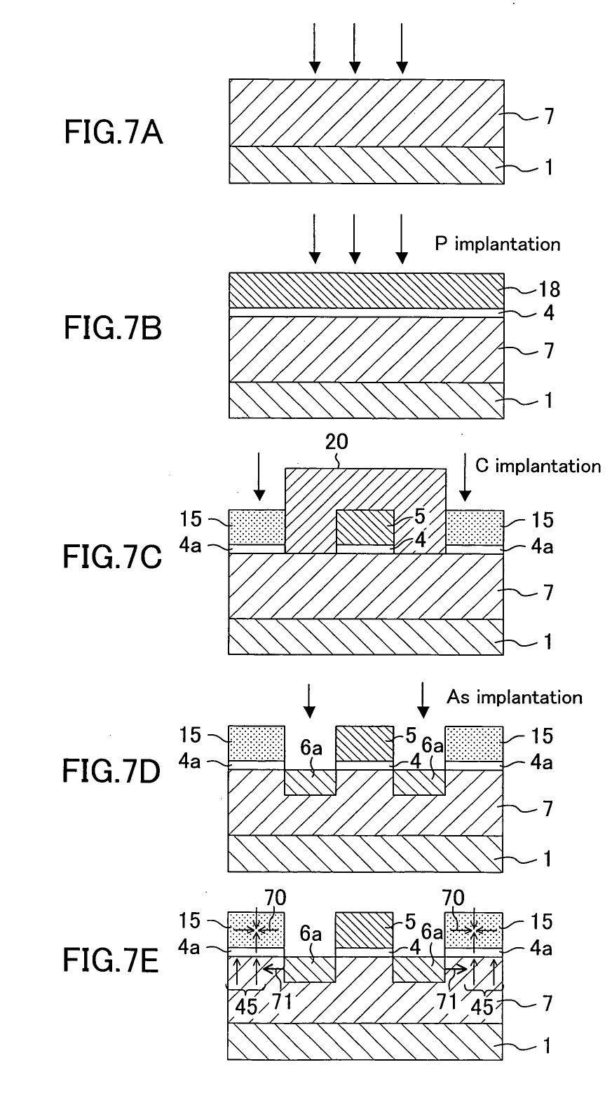

As a seventh embodiment of the present invention, a method for fabricating the semiconductor device of the sixth embodiment will be described. FIGS. 7A through 7E are cross-sectional views illustrating respective steps of a method for fabricating a MISFET according to the seventh embodiment.

First, as shown in FIG. 7A, a p-type impurity such as boron (B) is ion-implanted into a p-type substrate 1 (or a p-type semiconductor layer formed on the substrate 1) to form a p-type well 7 in the substrate 1. In this case, ion implantation is performed at an implantation energy of 300 keV and a dose of 1×10¹³ cm⁻². Next, a p-type impurity (such as B) is ion-implanted into part of the p-type well 7 at an implantation energy of 150 keV and a dose of 1×10¹³ cm⁻², thereby forming a punch through stopper. Moreover, a p-type impurity (such as B) is implanted into part of the substrate 1 which is to be a channel region at an implantation energy of 20 keV and a dose of 5×10¹² cm⁻². Next, an isolation region 3 is formed by a known method so as to surround an isolation region (not shown).

Next, as shown in FIG. 7B, a gate insulation film 4 is formed over the substrate 1 (p-type well 7) by thermal oxidation so as to have a thickness of 2 nm and then a polysilicon film (gate material film) 18 is formed over the substrate 1 so as to have a thickness of 150 nm. Thereafter, P is ion-implanted into the polysilicon film 18 at an implantation energy of 10 keV and a dose of 5×10¹⁵ cm⁻².

Subsequently, as shown in FIG. 7C, the polysilicon film 18 and the gate insulation film 4 are patterned by etching using a resist, thereby forming a gate electrode 5 on the gate insulation film 4 so as to extend onto the isolation region 3 and dummy gate electrodes 15 so as to be located on both sides of the gate electrode 5, respectively. Part of the gate insulation film 4 located under the gate electrode 5 is left and also parts of the gate insulation film 4 located under the dummy gate electrodes 15, respectively, are left as dummy gate insulation films 4a.

Next, a resist 20 is formed on the substrate 1 so as to have openings corresponding to at least the dummy gate electrodes 15. Thereafter, C is implanted into the dummy gate electrodes 15 of dummy transistors 95 at an implantation energy of 200 keV and a dose of 1×10¹⁵ cm⁻².

Next, as shown in FIG. 7D, As is ion-implanted into parts of the substrate 1 located on both sides of the gate electrode 5, respectively, at an implantation energy of 30 keV and a dose of 5×10¹⁵ cm⁻², thereby forming impurity doped regions 6a.

According to the above-described method, as shown in FIG. 7E, an intra-film tensile stress 70 can be generated in each of the dummy gate electrodes 15, thereby applying a tensile stress 45 in the substrate normal direction to each of the dummy gate electrodes 15. As a result, a tensile stress in the channel orientation can be applied to the channel region of the MISFET. As has been described, according to the fabrication method of this embodiment, the MISFET described in the sixth embodiment can be fabricated in a relatively simple manner. Even if some other impurity than C, which reduces the lattice constant of the polysilicon film 18, the same process steps as those described above can be performed.

In the step of performing ion implantation shown in FIG. 7C, implantation of C may be performed under a plurality of different conditions to achieve a uniform C distribution in the dummy gate electrodes 15. In this embodiment, implantation of C is performed after the polysilicon film 18 has been patterned. However, implantation of C may be performed before patterning of the polysilicon film 18. Also, implantation of C may be performed before implantation of P into the polysilicon film 18.

### First Modified Example of Seventh Embodiment

As a first modified example of the seventh embodiment of the present invention, a method in which C ions are implanted into the polysilicon film 18 before patterning of the polysilicon film 18 will be described.

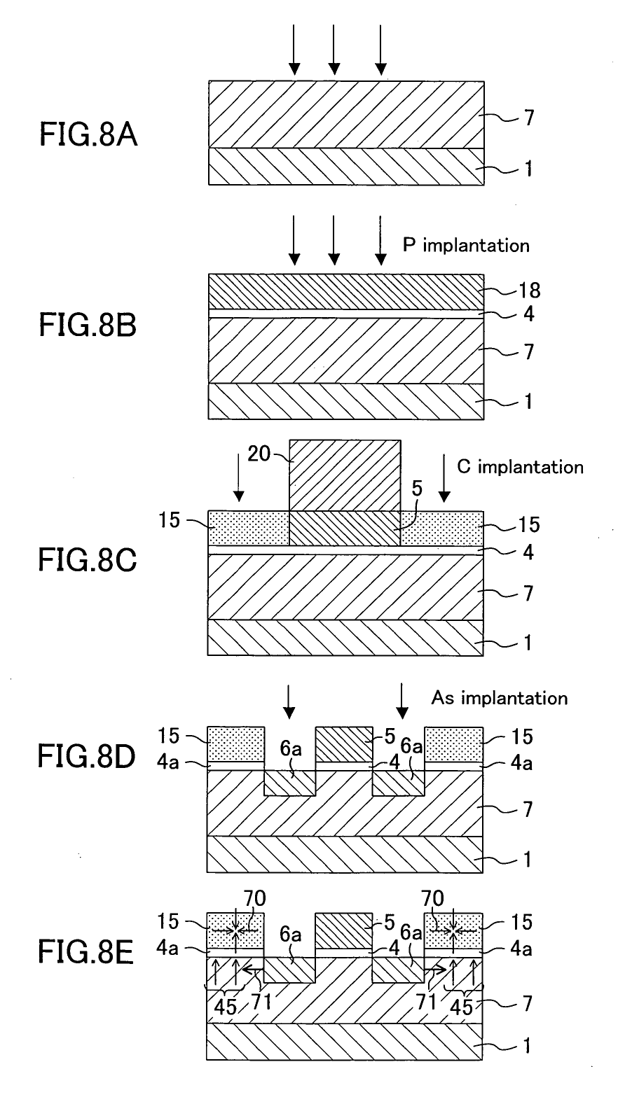

FIGS. 8A through 8E are cross-sectional views illustrating respective steps of a method for fabricating a semiconductor device according to the first modified example of the seventh embodiment.

First, as shown in FIGS. 8A and 8B, in the same manner as in the seventh embodiment, a gate insulation film 4 and a polysilicon film 18 are formed in this order on a substrate 1 and P ions are implanted into the polysilicon film 18.

Subsequently, as shown in FIG. 8C, a resist 20 is formed over the polysilicon film 18 so as to have openings corresponding to at least parts of the polysilicon film 18 which are to be dummy gate electrodes 15, and then C is implanted into exposed parts of the polysilicon film 18 at an implantation energy of 200 keV and a dose of 1×10¹⁵ cm⁻². In this case, considering an alignment error of the resist 20 and the like, it is preferable that the openings of the resist 20 are formed so as to be slightly larger than the parts of the polysilicon film 18 which are to be the dummy gate electrodes 15.

Next, as shown in FIG. 8D, after removal of the resist 20, another resist is formed over the polysilicon film 18 and a gate electrode 5, a gate insulation film 4, dummy gate electrodes 15 and dummy gate insulation films 4a are formed using the resist. The dummy gate electrodes 15 as well as the dummy gate insulation films 4a are located on both sides of the gate electrode 5, respectively. Subsequently, using the gate electrode 5 and the dummy gate electrodes 15 as a mask, As is ion-implanted, thereby forming impurity doped regions 6a.

According to the above-described method, the semiconductor device of the sixth embodiment can be also fabricated.

### Second Modified Example of Seventh Embodiment

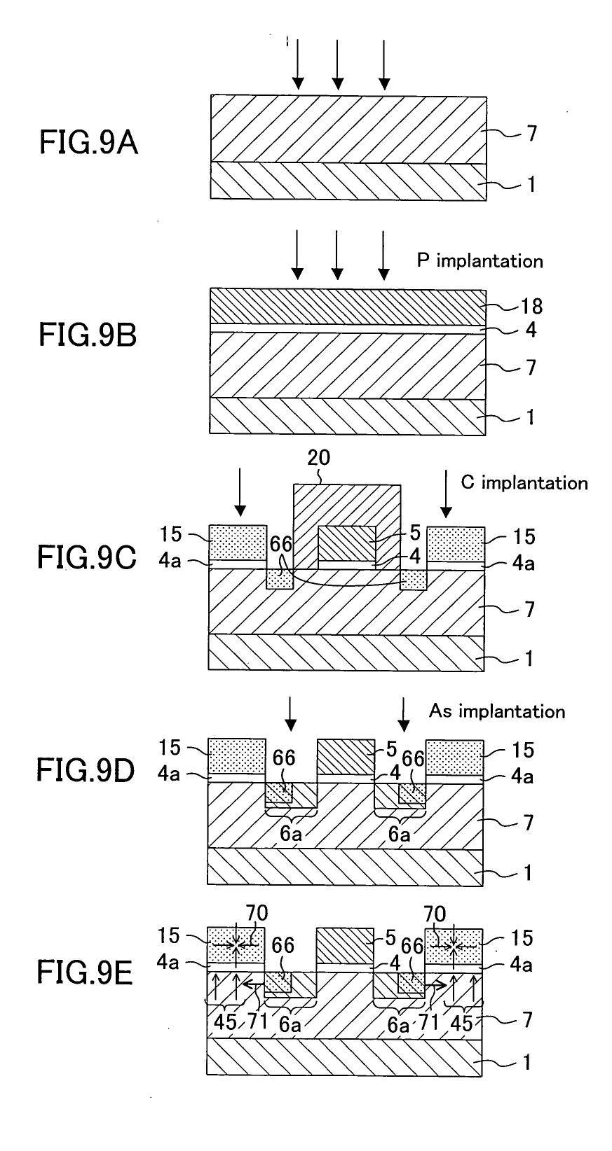

FIGS. 9A through 9E are cross-sectional views illustrating respective steps of a method for fabricating a semiconductor device according to a second modified example of the seventh embodiment. In this modified example, a method for fabricating a semiconductor device in which C is introduced into not only dummy gate electrodes 15 but also parts of impurity doped regions 6a of a MISFET will be described.

First, as shown in FIGS. 9A and 9B, in the same manner as in the seventh embodiment, a gate insulation film 4 and a polysilicon film 18 are formed in this order on a substrate 1 and P is ion implanted into the polysilicon film 18.

Next, as shown in FIG. 9C, the polysilicon film 18 and the gate insulation film 4 are patterned by etching using a resist, thereby forming a gate electrode 5, a gate insulation film 4 having a predetermined shape, dummy gate electrodes 15 and dummy gate insulation films 4a. Subsequently, a resist 20 is formed over the substrate 1 so as to have openings corresponding to the dummy gate electrodes 15 and part of the substrate 1 located between the gate electrode 5 and each of the dummy gate electrodes 15 and in the vicinity of each of the dummy gate electrodes 15. Then, C is ion implanted using the resist 20 to introduce C into the dummy gate electrodes 15 and the parts of the substrate 1 located in the vicinity (below and on a side of) of the dummy gate electrodes 15. Herein, the parts of the substrate 1 containing C are called tensile impurity doped regions 66.

Subsequently, as shown in FIG. 9D, after removal of the resist 20, ion implantation of As is performed using the gate electrode 5 as a mask, thereby forming impurity doped regions 6a in parts of the substrate 1 located on both sides of the gate electrode 5, respectively. Each of the tensile impurity doped regions 66 is provided in part of an associated one of the impurity doped regions 6a located below and on a side of an associated one of the dummy gate electrodes 15.

In the semiconductor device fabricated in the above-described manner, as shown in FIG. 9E, each of the tensile impurity regions 66 gives a tensile stress to the channel region of the MISFET after thermal diffusion of an impurity. Therefore, according to the method of this modified example, an n-channel type MISFET with improved carrier mobility can be fabricated.

### Eighth Embodiment

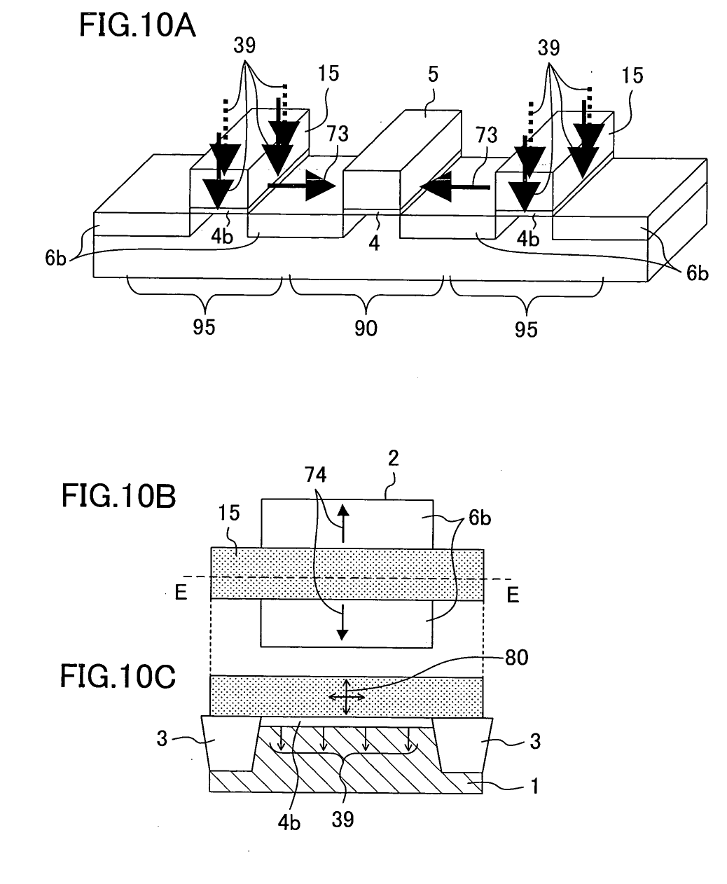

FIG. 10A is a perspective view illustrating a semiconductor device according to an eighth embodiment of the present invention. FIG. 10B is a plan view of a dummy transistor of the semiconductor device of this embodiment. FIG. 10C is a cross-sectional view taken along the line E-E of FIG. 10B. The semiconductor device of this embodiment includes a p-channel type MISFET 90 and dummy transistors located in both sides of the MISFET 90, respectively, and including respective dummy gate electrodes in which an impurity which generates a stress is introduced.

The p-channel type MISFET 90 includes a gate insulation film 4, a gate electrode 5 containing a p-type impurity and impurity doped regions 6b provided in parts of a substrate 1 located on both sides of the gate electrode 5, respectively, and containing a p-type impurity.

The semiconductor device of this embodiment basically has the same structure as the structure of the semiconductor device of the sixth embodiment and has the following characteristics.

As the substrate 1 of dummy transistors 95 and the MISFET 90, a substrate with a <110> channel orientation, a <100> channel orientation or the like is used.

The dummy transistors 95 include respective dummy gate insulation films 4b each at least having part located on an active region 2 and respective dummy gate electrodes 15 provided on the dummy gate insulation films 4b, respectively. A material which increases a lattice constant of a material (for example, polysilicon) forming the dummy gate electrodes 15 and does not affect the generation of carries in the MISFET 90 is introduced into each of the dummy gate electrodes 15. In this case, as an impurity to be introduced into the dummy gate electrodes 15, Ge or Sn is specifically preferable. However, As, Ga or some other material may be used.

In this manner, an intra-film compressive stress 80 is generated in each of the dummy gate electrodes 15. The intra-film compressive stress 80 causes the generation of a compressive stress 39 in the substrate normal direction in parts of the substrate 1 located under the dummy gate electrodes 15, respectively, and the generation of a compressive stress 73 (which is the same as the tensile stress 74 when viewed from each of the dummy transistors 95) in the channel orientation in a channel region of the MISFET 90.

When the substrate 1 is, for example, a silicon substrate of which a principal plane is some other crystal plane than a <100> plane, the compressive stress 73 increases the mobility of carries. Accordingly, in the semiconductor device of this embodiment, the mobility of carries is improved in the MISFET 90 and performance thereof is improved.

As has been described, a MISFET according to the present invention is applicable to various kinds electric equipment.

What is claimed is:

1. A semiconductor device comprising:
a substrate including an active region formed therein;
an isolation region formed in the substrate so as to surround the active region;
a gate insulation film formed on the active region;
a gate electrode formed on the gate insulation film so as to extend onto the isolation region;
impurity doped regions formed in parts of the active region located in both sides of the gate electrode, respectively, and containing a first impurity having a conductivity type,
wherein the gate electrode includes first part located on the isolation region and second part located on the active region, and
wherein the first part of the gate electrode includes a larger stress than a stress in the second part of the gate electrode.

2. The semiconductor device of claim 1, wherein the first part of the gate electrode contains a second impurity which changes a lattice constant of the gate electrode.

3. The semiconductor device of claim 2, wherein the second part of the gate electrode contains the second impurity at a lower concentration than a concentration of the second impurity in the first part.

4. The semiconductor device of claim 2, wherein the second impurity is an impurity which does not have a conductivity type.

5. The semiconductor device of claim 2, wherein the first impurity is an n-type impurity, and
wherein the second impurity is an impurity which increases the lattice constant of the gate electrode.

6. The semiconductor device of claim 2, wherein the gate electrode is formed of polysilicon, and
wherein the second impurity is germanium.

7. The semiconductor device of claim 2, wherein the first impurity is an n-type impurity, and
wherein the second impurity is an impurity having the same conductivity type as the conductivity type of the first impurity.

8. The semiconductor device of claim 2, wherein the first impurity is a p-type impurity, and
wherein the second impurity is an impurity which reduces the lattice constant of the gate electrode.

9. The semiconductor device of claim 2, wherein the gate electrode is formed of polysilicon, and
wherein the second impurity is carbon.

10. The semiconductor device of claim 1, further comprising:
a dummy gate electrode formed over the substrate so as to face the gate electrode with an associated one of the impurity doped regions interposed between the dummy gate electrode and the gate electrode and containing a third impurity which changes an intrinsic lattice constant of a material forming the dummy gate electrode.

11. The semiconductor device of claim 10, wherein the first impurity is an n-type impurity, and
wherein the third impurity is an impurity which reduces the lattice constant of the dummy gate electrode.

12. The semiconductor device of clam 11, wherein the dummy gate electrode is formed of polysilicon, and
wherein the third impurity is carbon.

13. The semiconductor device of claim 10, wherein the first impurity is a p-type impurity, and
wherein the third impurity is an impurity which increases the lattice constant of the dummy gate electrode.

14. The semiconductor device of claim 13, wherein the dummy gate electrode is formed of polysilicon, and
wherein the third impurity is germanium or tin.

15. The semiconductor device of claim 10, wherein the third impurity is contained in part of an associated one of the impurity regions located below and on a side of the dummy gate electrode.

16. The semiconductor device of claim 10, wherein the dummy gate electrode is provided over the isolation region and the active region.

17. A semiconductor device comprising:
a substrate including an active region formed therein;
an isolation region formed in the substrate so as to surround the active region;
a gate insulation film formed on the active region;
a gate electrode provided on the gate insulation film;
impurity doped regions formed in parts of the active region located on both sides of the gate electrode, respectively, and containing a first impurity having a conductivity type; and
a dummy gate electrode provided over the substrate so as to face the gate electrode with an associated one of the impurity doped regions interposed between the dummy gate electrode and the gate electrode and containing a second impurity which changes an intrinsic lattice constant of a material forming the dummy gate electrode.

18. The semiconductor device of claim 17, wherein the first impurity is an n-type impurity, and
wherein the second impurity is an impurity which reduces the lattice constant of the dummy gate electrode.

19. The semiconductor device of claim 17, wherein the first impurity is a p-type impurity, and
wherein the second impurity is an impurity which increases the lattice constant of the dummy gate electrode.

20. A method for fabricating a semiconductor device, the method comprising the steps of:
a) forming an isolation region in a substrate;
b) forming a gate insulation film on an active region formed in part of the substrate surrounded by the isolation region;
c) forming a gate electrode on the gate insulation film so as to extend onto the isolation region;
d) making first part of the gate electrode located on the isolation region contain a larger stress than a stress in second part of the gate electrode located on the active region; and
e) forming impurity doped regions in parts of the active region located on both sides of the gate electrode, respectively, each of the impurity regions containing a first impurity having a conductivity type.

21. The method of claim 20, wherein in the step d), a second impurity which changes a lattice constant of the gate electrode is selectively implanted into the first part of the gate electrode, thereby making the first part include a larger stress than a stress in the second part of the gate electrode.

22. The method of claim 21, wherein in the step c), the second impurity is implanted into the gate electrode patterned at a smaller dose than a dose of the second impurity to be implanted in the step d).

23. The method of claim 21, wherein the second impurity is an impurity which does not have a conductivity type.

24. The method of claim 21, wherein the first impurity is an n-type impurity, and
wherein the second impurity is an impurity which increases a lattice constant of the gate electrode.

25. The method of claim 21, wherein the first impurity is a p-type impurity, and
wherein the second impurity is an impurity which reduces a lattice constant of the gate electrode.

26. The method of claim 20, further comprising the step f) of forming, on a side of the gate electrode, a dummy gate electrode containing a third impurity which changes an intrinsic lattice constant of a material forming the dummy gate electrode,
wherein in the step e), the impurity doped regions are formed so that each of the impurity doped regions is located between the dummy gate electrode and the gate electrode.

27. A method for fabricating a semiconductor device, the method comprising the steps of:
a) forming, in a substrate including an active region formed therein, an isolation region so as surround the active region;
b) forming a gate insulation film and a gate electrode over the active region;
c) forming, at least in part of the substrate located over the active region and on a side of the gate electrode, a dummy gate electrode containing a first impurity which changes an intrinsic lattice constant of a material forming the dummy gate electrode; and
d) forming impurity doped regions each containing a second impurity having a conductivity type in parts of the active region located on both sides of the gate electrode, respectively, each of the parts being located between the gate electrode and the dummy gate electrode.

28. The method of claim 27, wherein the step c) includes the steps of
c1) forming a gate material film over the substrate,
c2) patterning the gate material film to form the dummy gate electrode on a side of the gate electrode, and
c3) introducing the first impurity which changes a lattice constant of the gate material film at least into the dummy gate electrode,
wherein the step c2) is performed simultaneously with the step b).

29. The method of claim 28, wherein the step c3), the first impurity is also introduced into part of the active region located between the gate electrode and the dummy gate electrode and in the vicinity of the dummy gate electrode to form a tensile impurity region, and
wherein in the step d), the impurity doped regions are formed in the parts of the active region including the tensile impurity region.

30. The method of claim 27, wherein in the step c) includes the steps of
c4) forming a gate material film over the substrate,
c5) introducing the first impurity which changes a lattice constant of the gate material film in part of the gate material film, and
c6) patterning the gate material film to form the dummy gate electrode containing the first impurity,
wherein the step c6) is performed simultaneously with the step b) and the gate electrode formed in the step b) is formed of part of the gate material film in which the first impurity is not implanted in the step c5).

31. The method of claim 27, wherein the second impurity is an n-type impurity, and
wherein the first impurity is an impurity which reduces a lattice constant of the gate material film.

32. The method of claim 27, wherein the second impurity is a p-type impurity, and
wherein the first impurity is an impurity which increases a lattice constant of the gate material film.
